(19) United States
(12) Patent Application Publication
(10) Pub. No.: US 2012/0286405 A1
(43) Pub. Date: Nov. 15, 2012

(54) SEMICONDUCTOR DEVICE AND METHOD FOR MANUFACTURING THE SAME

(75) Inventor: Kei TOYOTA, Osaka (JP)

(73) Assignee: Panasonic Corporation, Osaka (JP)

(21) Appl. No.: 13/457,585

(22) Filed: Apr. 27, 2012

(30) Foreign Application Priority Data
May 13, 2011 (JP) 2011-108292

(51) Int. Cl. H01L 23/29; H01L 23/49; H01L 21/56; H01L 23/495

(52) U.S. Cl. 257/666; 257/791; 257/784; 438/127; 257/E23.12; 257/E23.031; 257/E23.024; 257/E21.502

(57) ABSTRACT

A semiconductor device according to the present invention includes a substrate, a semiconductor element which is mounted on the substrate, a protecting film which covers at least a part of the semiconductor element, and an encapsulation resin which encapsulates the semiconductor element and the protecting film, wherein between the protecting film and the encapsulation resin, there is at least one gap in which the protecting film does not stick to the encapsulation resin. According to the above mentioned configuration, it is possible to provide a semiconductor device having a superior stress-relief performance.

### BACKGROUND OF THE INVENTION

1. Field of the Invention

The present invention relates to a semiconductor device and a method for manufacturing the same.

2. Related art of the Invention

Due to the miniaturization of electronic equipment in recent years, it is also required that semiconductor devices which are included in the electronic equipment are highly densified and their performances are promoted. As a result, due to the highly densified of the semiconductor device, fine connecting portion increases and the semiconductor device itself becomes thin. Since the highly densified semiconductor device like this has decreased tolerance for the thermal stress etc. in comparison with a conventional semiconductor device, the further improvement for maintaining the reliability of semiconductor device is demanded.

As a structure satisfying the demand like this, the structure shown in FIG. 10 has been proposed (see, for example, Japanese Patent Document JP 09-321182). In the case of the structure shown in FIG. 10, a semiconductor element 101 is disposed on a circuit board 102 using a mounting member 106. The semiconductor element 101 is wire-bonded with circuit board terminals 105 using bonding metal wires 103. A part of this semiconductor element 101 is covered by silicone rubber 107 to be protected. Further, an encapsulation resin layer 104 made from encapsulation resin 108 is formed above the silicone rubber 107 and the semiconductor element 101.

That is, after the semiconductor element 101 is mounted on the circuit board 102, monomer material of the silicone rubber 107 is mounted so as to cover a part of the semiconductor element 101 and is heated and cured in order to form a protecting film, and then the semiconductor element 101 is further encapsulated with the encapsulation resin 108 so as to make the encapsulation resin 108 and the protecting film closely into contact, so that the semiconductor device is completed.

In the case of the semiconductor device like this, since deformation of the silicone rubber 107 having an elastic modulus which is lower than the surrounding materials relieves the stress caused by the difference of the thermal expansion coefficient of each material constituting the semiconductor device, generation of exfoliation and the like can be reduced.

### SUMMARY OF THE INVENTION

### Technical Problems

However, in the above mentioned patent document JP 09-321182, an epoxy and silicone elastomer resin composition is used as the silicone rubber 107 forming the protecting film, and a reactive functional group existing on the surface of the silicone rubber 107 comprises at least one of an epoxy group, an alkoxyl group, a silanol group, a hydroxyl group, and an amino group, and as a result, the adhesion performance between the protecting film and the encapsulation resin 108 comprising epoxy resin composition becomes higher.

Therefore, since the protecting film of the silicone rubber 107 covering a part of the semiconductor element 101 is stuck fast to the encapsulation resin 108, relief of the stress has a limit.

In view of the above-mentioned problem of the conventional semiconductor device, the present invention is directed to a semiconductor device having a superior stress-relaxation performance and a method for manufacturing the same.

### Means for Solving the Problems

To achieve the above described purpose of the present invention, the 1^{st} aspect of the present invention is a semiconductor device comprising:

a substrate;

a semiconductor element which is mounted on the substrate;

a protecting film which covers at least a part of the semiconductor element; and

an encapsulation resin which encapsulates the semiconductor element and the protecting film,

wherein between the protecting film and the encapsulation resin, there is at least one gap in which the protecting film does not stick to the encapsulation resin.

The 2^{nd} aspect of the present invention is the semiconductor device according to the 1^{st} aspect of the present invention, wherein the protecting film has a water repellency.

The 3^{rd} aspect of the present invention is the semiconductor device according to the 1^{st} aspect of the present invention, wherein the protecting film is made from a silicone rubber material having interfacial tension energy that is not less than 15 mN/m and not more than 30 mN/m, and

interfacial tension energy of the encapsulation resin is not less than 40 mN/m and not more than 60 mN/m.

The 4^{th} aspect of the present invention is the semiconductor device according to the 1^{st} aspect of the present invention, wherein the protecting film has a thickness which is not less than 10 μm and not more than 2000 μm, and

the protecting film has an elastic modulus which is not less than 0.5 MPa and not more than 10 MPa under conditions of 25° C. to 260° C.

The 5^{th} aspect of the present invention is the semiconductor device according to the 1^{st} aspect of the present invention, wherein the protecting film is made from a silicone rubber material,

a precursor of the silicone rubber material has an organopolysiloxane framework, and

the precursor is cured in a thermosetting reaction due to a hydrosilylation reaction, so that the precursor becomes silicone rubber having a siloxane framework.

The 6^{th} aspect of the present invention is the semiconductor device according to the 1^{st} aspect of the present invention, wherein a thickness of the gap is not less than 0.1 μm and not more than 100 μm.

The 7^{th} aspect of the present invention is the semiconductor device according to the 1^{st} aspect of the present invention, wherein the substrate is a lead frame,

the semiconductor element and an external terminal of the lead frame are connected with a bonding metal wire, and

the protecting film covers a connecting portion of the bonding metal wire, at which the bonding metal wire is connected to the semiconductor element.

The 8^{th} aspect of the present invention is the semiconductor device according to the 1^{st} aspect of the present invention, wherein the substrate is a circuit board,

the semiconductor element and an electrode portion of the circuit board are connected with a bonding metal wire, and

the protecting film covers a connecting portion of the bonding metal wire, at which the bonding metal wire is connected to the semiconductor element.

The 9^{th} aspect of the present invention is the semiconductor device according to the 1^{st} aspect of the present invention, wherein the substrate is a circuit board,

an electrode pad of the semiconductor element and an electrode pad of the circuit board are connected with a soldering portion,

a region in which the soldering portion is disposed is filled with an underfill resin,

the protecting film covers the semiconductor element and a fillet portion of the underfill resin,

the encapsulation resin encapsulates the semiconductor element, the fillet portion of the underfill resin, and the protecting film, and

an another gap is formed between the protecting film and the fillet portion of the underfill resin.

The 10^{th} aspect of the present invention is the semiconductor device according to the 1^{st} aspect of the present invention, wherein the encapsulation resin is an epoxy resin,

the protecting film is made from a silicone rubber material,

a precursor of the silicone rubber material has an organopolysiloxane framework, and

the precursor is cured in a thermosetting reaction due to a hydrosilylation reaction, so that the precursor becomes silicone rubber having a siloxane framework.

A 11^{th} aspect of the present invention is a method for manufacturing a semiconductor device comprising:

putting a precursor of a protecting film so as to cover at least a part of a semiconductor element mounted on a substrate;

forming the protecting film due to polymerization of the precursor; and

encapsulating the semiconductor element and the protecting film with an encapsulation resin, and forming, between the protecting film and the encapsulation resin, at least one gap in which the protecting film does not stick to the encapsulation resin.

The 12^{th} aspect of the present invention is the method for manufacturing a semiconductor device according to the 11^{th} aspect of the present invention,

wherein the precursor of the protecting film is a silicone rubber monomer.

The 13^{th} aspect of the present invention is the method for manufacturing a semiconductor device according to the 11^{th} aspect of the present invention,

wherein in the case of encapsulating the semiconductor element and the protecting film with the encapsulation resin, the encapsulation resin is made from material which has bad wettability to the protecting film.

### Advantageous Effects of the Invention

As described above, according to the present invention, it is possible to provide a semiconductor device having a superior stress-relief performance and a method for manufacturing the same.

### BRIEF DESCRIPTION OF THE DRAWINGS

FIG. 1 is a schematic sectional view illustrating a semiconductor device according to first embodiment of the present invention;

FIG. 2A is a schematic sectional view illustrating a method for manufacturing the semiconductor device according to first embodiment of the present invention;

FIG. 2B is a schematic sectional view illustrating a method for manufacturing the semiconductor device according to first embodiment of the present invention;

FIG. 2C is a schematic sectional view illustrating a method for manufacturing the semiconductor device according to first embodiment of the present invention;

FIG. 2D is a schematic sectional view illustrating a method for manufacturing the semiconductor device according to first embodiment of the present invention;

FIG. 2E is a schematic sectional view illustrating a method for manufacturing the semiconductor device according to first embodiment of the present invention;

FIG. 3 is a schematic sectional view illustrating a semiconductor device according to second embodiment of the present invention;

FIG. 4A is a schematic sectional view illustrating a method for manufacturing the semiconductor device according to second embodiment of the present invention;

FIG. 4B is a schematic sectional view illustrating a method for manufacturing the semiconductor device according to second embodiment of the present invention;

FIG. 4C is a schematic sectional view illustrating a method for manufacturing the semiconductor device according to second embodiment of the present invention;

FIG. 4D is a schematic sectional view illustrating a method for manufacturing the semiconductor device according to second embodiment of the present invention;

FIG. 4E is a schematic sectional view illustrating a method for manufacturing the semiconductor device according to second embodiment of the present invention;

FIG. 5 is a schematic sectional view illustrating a semiconductor device according to third embodiment of the present invention;

FIG. 6A is a schematic sectional view illustrating a method for manufacturing the semiconductor device according to third embodiment of the present invention;

FIG. 6B is a schematic sectional view illustrating a method for manufacturing the semiconductor device according to third embodiment of the present invention;

FIG. 6C is a schematic sectional view illustrating a method for manufacturing the semiconductor device according to third embodiment of the present invention;

FIG. 6D is a schematic sectional view illustrating a method for manufacturing the semiconductor device according to third embodiment of the present invention;

FIG. 6E is a schematic sectional view illustrating a method for manufacturing the semiconductor device according to third embodiment of the present invention;

FIG. 7 is a schematic sectional view illustrating a semiconductor device according to a variation of the first embodiment of the present invention;

FIG. 8 is a schematic sectional view illustrating a semiconductor device according to a variation of the second embodiment of the present invention;

FIG. 9 is a schematic sectional view illustrating a semiconductor device according to a variation of the first embodiment of the present invention; and

FIG. 10 is a schematic sectional view illustrating the conventional semiconductor device having the protecting film of the semiconductor element and encapsulated with the encapsulation resin.

### PREFERRED EMBODIMENTS OF THE INVENTION

Embodiments according to the present invention will be described in detail below based on the drawings.

### Embodiment 1

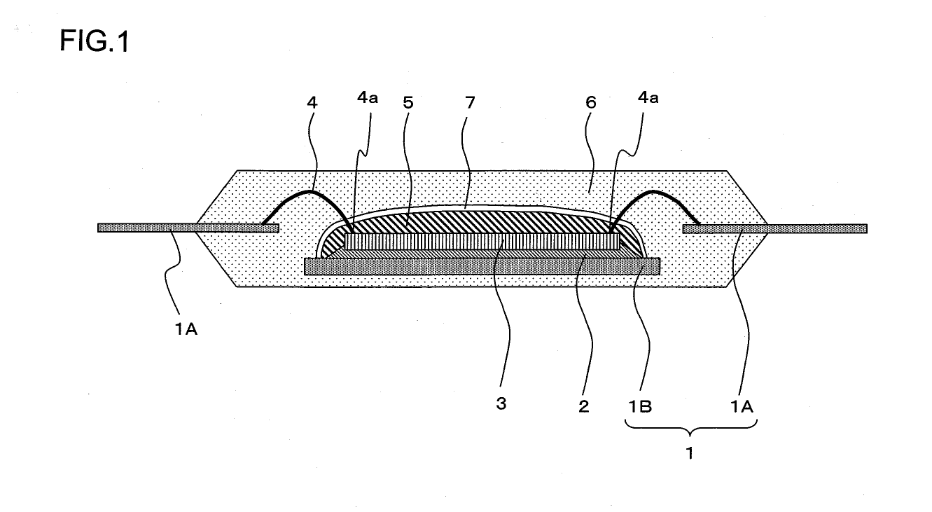

FIG. 1 is a schematic sectional view illustrating configuration of a semiconductor device of Embodiment 1 according to the present invention. As shown in FIG. 1, the semiconductor device of the present Embodiment 1 comprises a lead frame 1 having a die pad part 1B and external terminals 1A, a semiconductor element 3 mounted on the die pad part 1B via a paste material 2, and bonding metal wires connecting between the semiconductor element 3 and the external terminals 1A. Further, in the case of the semiconductor device of the present Embodiment 1, the semiconductor element 3 is covered by a protecting film 5 of water repellent silicone rubber. An encapsulation resin 6 covers the external terminals 1A of the lead frame 1, the die pad part 1B, the semiconductor element 3, the protecting film 5 and the bonding metal wires 4 so as to encapsulate them, while each the tip portion of the external terminals 1A is exposed from the encapsulation resin 6. Incidentally, connecting portions 4a of the bonding metal wires 4, which have been connected to the semiconductor element 3, are also covered by the protecting film 5 of the water repellent silicone rubber. And a gap layer 7 corresponding to one example of a gap of the present invention is formed between the protecting film 5 and the encapsulation resin 6. By the way, the lead frame 1 of the present Embodiment 1 is one example of a substrate of the present invention. The thickness of the gap layer 7 of FIG. 1 is exaggeratedly illustrated, and the other figures described later are the same.

The lead frame 1 is made from material, such as copper, superior in thermal conductivity and electric conductivity. The encapsulation resin 6 is not restricted, and a known thermosetting epoxy resin, in which, for example, an ortho-cresol novolac epoxy resin as an essential material and a phenol resin as a curing agent which can cure the essential material are blended, and then about 70 to 90 PHR (Per Hundred Resin) of an inorganic filler is blended, can be employed.

The above described protecting film 5 of water repellent silicone rubber and the gap layer 7 constituted by the protecting film 5 are the important portions of the present invention, and the details thereof will be described below.

The material of the protecting film 5 is not restricted, however it is preferable to employ a silicone rubber which is formed by curing a silicone rubber precursor having hydrophobic functional group and which has interfacial tension energy that is not less than 15 mN/m and not more than 30 mN/m after the curing. The protecting film 5 can include an inorganic filler. In this case, since the volume resistivity increases, defects such as migration or short-circuit between bonding metal wires 4 can be prevented more certainly.

As a precursor of liquid silicone rubber, a known mixture of an organopolysiloxane including vinyl group, a hydrogen organopolysiloxane and a curing catalyst such as a platinum, which is disclosed by the prior document of Origin Technical Journal No. 67 (2004) 111-7, can be employed, and there is no limitation one-pack type or two-packs type. That is, as the fundamental chemical structures of the precursor of liquid silicone rubber, the principal chain structure is a siloxane framework structure, and an alkyl group or a fluoroalkyl group or both of them is combined with a silicon atom. Further, a reactive site, such as a vinyl group, required for the combination between the siloxane frameworks is combined with a terminal of the siloxane framework.

When additionally curing the above mentioned mixture with heat by the conventional method, a hydrosilylation reaction takes place, so that the precursor becomes the protecting film which has a chemical stability, a low elastic modulus and compact structure without a defect. It is especially preferable that the functional group combined with silicon atom is hydrocarbon system according to the necessity of a water repellency.

The above mentioned organopolysiloxane which is the precursor of the silicone rubber can be produced by the conventional method in which, for example, after the organopolysiloxane is polymerized in the presence of a strong acid, water and specific organosilicon compound are added.

The protecting film 5 formed like this has the interfacial tension energy that is not less than 15 mN/m and not more than 30 mN/m after the curing, and has the water repellency. The interfacial tension energy of the encapsulation resin 6 made from an epoxy system thermosetting resin is not less than 40 mN/m and not more than 60 mN/m, and the protecting film 5 dose not stick to the encapsulation resin 6 during the encapsulation process and subsequent curing process, so that the gap layer 7 is formed on the interface.

By the way, if the interfacial tension energy of the protecting film 5 is less than 15 mN/m, the maintenance of the form of the protecting film 5 itself becomes difficult, and as a result, since the protecting film 5 loses its shape in the encapsulation process of the encapsulation resin 6, it is not desirable. On the other hand, if the interfacial tension energy of the protecting film 5 is more than 30 mN/m, the sufficient water repellency is not obtained, and as a result, since the protecting film 5 sticks to the encapsulation resin 6, the configuration of the present embodiment can not be obtained.

However, since the encapsulation resin 6 has superior adhesive properties with the metal because the encapsulation resin 6 reacts on a functional group on the surface of the metal at the time of curing, the encapsulation resin 6 sticks to the lead frame 1 except for the portion covered by the protecting film 5. Specifically, the encapsulation resin 6 sticks to a portion which does not connected with the protecting film 5 on the die pad part 1B and the external terminals 1A. Therefore, the protecting film 5 and the semiconductor element 3 covered by the protecting film 5 are fixed in a package, and it is possible to maintain sufficient strength in the whole package.

The elastic modulus of the protecting film 5 after curing process is not less than 0.5 MPa and not more than 10 MPa under the conditions of 25° C. (room temperature) to 260° C. (reflow temperature).

The thickness of the gap layer 7 is not less than 0.1 μm and not more than 100 μm.

Next, a method for manufacturing the semiconductor device of Embodiment 1 according to the present invention will be described.

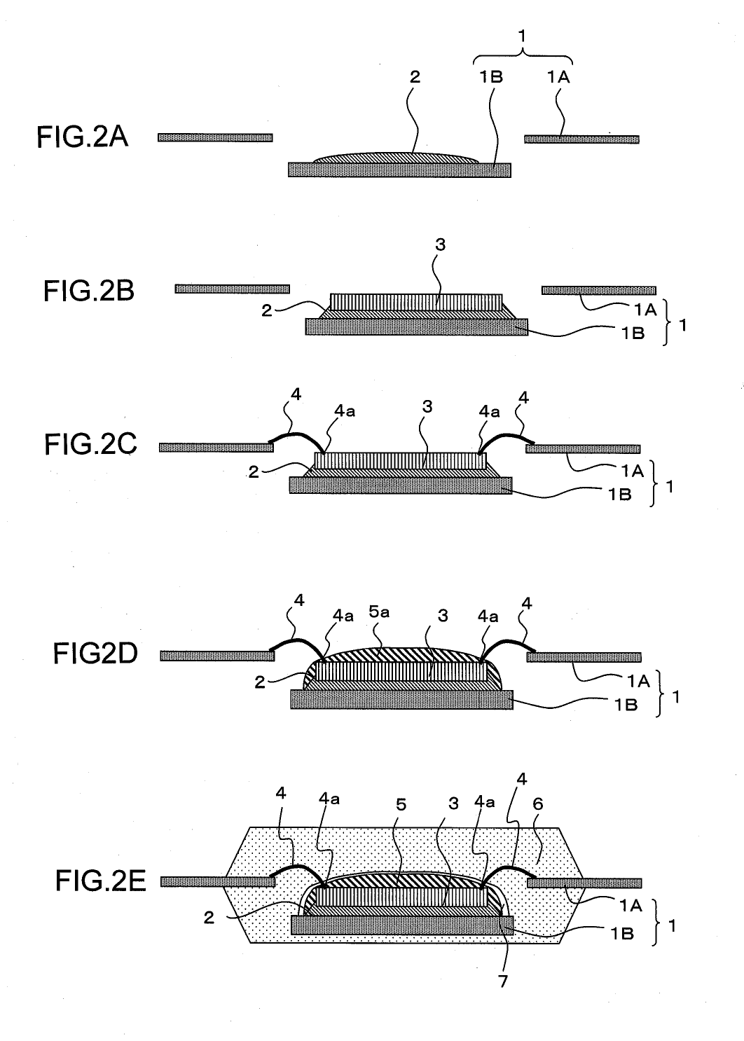

Each of FIGS. 2A to 2E is schematic sectional view illustrating the method for manufacturing the semiconductor device according to Embodiment 1.

As shown in FIG. 2A, an appropriate quantity of a paste material 2 is applied on the die pad part 1B of the lead frame 1. Further, as shown in FIG. 2B, the semiconductor element 3 is mounted on the paste material 2. A known dispenser can be used in case of the application of the paste material 2, and a known die bonder can be used in case of mounting the semiconductor element 3.

Then, as shown in FIG. 2C, the semiconductor element 3 and the external terminals 1A of the lead frame 1 are joined electrically and mechanically with the bonding metal wires 4. A known wire bonder can be used in case of bonding the bonding metal wires 4.

Then, as shown in FIG. 2D, an appropriate quantity of a silicone rubber monomer 5a that is a precursor of the protecting film 5 is dropped on a portion of the semiconductor element 3, which comes in contact with air, and is dropped on a portion of the paste material 2, which comes in contact with air. In this case, silicone rubber monomer 5a is dropped also on the connecting portions 4a of the bonding metal wires 4, which have been connected to the semiconductor element 3. It is preferable that the quantity of the silicone rubber monomer 5a to be dropped becomes the thickness, which is not less than 10 μm and not more than 2000 μm, of the silicone rubber cured by the method described later. If the thickness of the silicone rubber is less than 10 μm, it is not expectable that thermal stress which is generated at the time of heating in the reflow process and the like is relaxed enough. If the thickness of the silicone rubber is more than 2000 μm, as described later, the thickness of the encapsulation resin 6 becomes thin, and as a result, the strength of the thin portion of the encapsulation resin 6 becomes weak. The thickness of a whole semiconductor device of Embodiment 1 is 5 mm.

As the silicone rubber monomer 5a, a mixture of an organopolysiloxane, in which an alkyl group is combined with a silicon atom, and a curing catalyst such as a platinum can be employed. After the silicone rubber monomer 5a is dropped, the dropped silicone rubber monomer 5a is heated at 150° C. for 4 hours, and as a result, the protecting film 5 is obtained. By the way, the above mentioned process of dropping the silicone rubber monomer 5a corresponds to one example of a process (a putting process) of the present invention, in which a precursor of a protecting film is putted so as to cover at least a part of a semiconductor element mounted on a substrate. The above mentioned process of heating the dropped silicone rubber monomer 5a corresponds to one example of a process (a polymerization process) of the present invention, in which the protecting film is formed due to polymerization of the precursor.

The semiconductor element 3 shown in FIG. 2D, which has been covered with the protecting film 5 but has not yet been encapsulated with the encapsulation resin 6, is placed into a sealing mold heated at suitable temperature. Then, as shown in FIG. 2E, the encapsulation resin 6 of the epoxy system thermosetting resin is filled into the sealing mold under pressure by using the transfer molding method, so that the epoxy system thermosetting resin is cured. The above mentioned process, in which the epoxy system thermosetting resin is filled into the sealing mold with pressure to be cured, corresponds to one example of a process (an encapsulation process) of the present invention, in which the semiconductor element and the protecting film are encapsulated with an encapsulation resin, and, between the protecting film and the encapsulation resin, at least one gap in which the protecting film does not stick to the encapsulation resin is formed. When the epoxy system thermosetting resin(encapsulation resin 6) is cured, the surface of the epoxy system thermosetting resin does not stick to hardening body of the silicone rubber forming the protecting film 5 completely, because the interfacial tension energy of the epoxy system thermosetting resin is not less than 40 mN/m and not more than 60 mN/m. Since the material which has bad wettability to the encapsulation resin 6 is used like this as the material of the protecting film 5, the encapsulation resin 6 does not stick to the protecting film 5 completely, and then the gap layer 7 is formed, so that the semiconductor device of Embodiment 1 according to the present invention as shown in FIG. 1 is produced.

In the case of the semiconductor device of Embodiment 1, as described above, since the gap layer 7 is formed between the protecting film 5 and the encapsulation resin 6, the relief of the internal stress which is caused by the difference of the linear expansion coefficients between encapsulation resin 6 and the other members constituting the semiconductor device can be very effectively performed.

Meanwhile, as described above, in the case of Japanese Patent Document JP 09-321182, an epoxy and silicone elastomer resin composition is used as the silicone rubber 107, and a reactive functional group existing on the surface of the silicone rubber 107 comprises at least one of an epoxy group, an alkoxyl group, a silanol group, a hydroxyl group, and an amino group. Since each of these functional groups is hydrophilic and water stays in a gap between the epoxy resin(encapsulation resin layer 104) and the silicone rubber 107 even if the gap is slight exfoliation between the epoxy resin composition and the silicone rubber 107, there is a technical problem of causing the fall of reliability in the reflow process and the like.

However, in the present Embodiment 1, since the protecting film 5 of water repellent silicone rubber is used, generating of the inferior goods at the time of reflow process because of permeation of the water from the outside can be reduced.

That is, the protecting film 5 made from hardening body of the silicone rubber has a water repellency, because interfacial tension energy of the protecting film 5 made from hardening body of the silicone rubber is not less than mN/m and not more than 30 mN/m, and on the contrary, interfacial tension energy of water is about 72 mN/m. Therefore, water does not stay in the gap layer 7 between the encapsulation resin 6 made from the epoxy system thermosetting resin and the protecting film 5 made from hardening body of the silicone rubber. Even if water stays in the gap layer 7, the water can not permeate the hardening body of the silicone rubber, because the hardening body of the silicone rubber has a lower interfacial tension.

As described above, fall of reliability resulting from the permeation of the water from the outside is suppressed, and generating of stress caused by heat modification of each member of the semiconductor device is also relieved by the gap layer 7. That is, according to the semiconductor device of the present invention, since the fall of reliability resulting from the permeation of the water from the outside and the fall of reliability resulting from the thermal stress are suppressed simultaneously, long-life of the semiconductor device is realizable.

Incidentally, in the present embodiment, a silicone rubber monomer cured by heat as the material for forming the protecting film 5 is used. However, the present invention is not limited to this. For instance, a silicone rubber monomer which can be cured by light or both light and heat can also be used.

### Embodiment 2

Next, Embodiment 2 according to the present invention will be described in detail below based on the drawings. In the case of a semiconductor device of the present Embodiment 2, a semiconductor element 3 is disposed on a circuit board, which is different from Embodiment 1. The same reference numerals as them of Embodiment 1 are given to constitutional parts of Embodiment 2 corresponding to them of Embodiment 1.

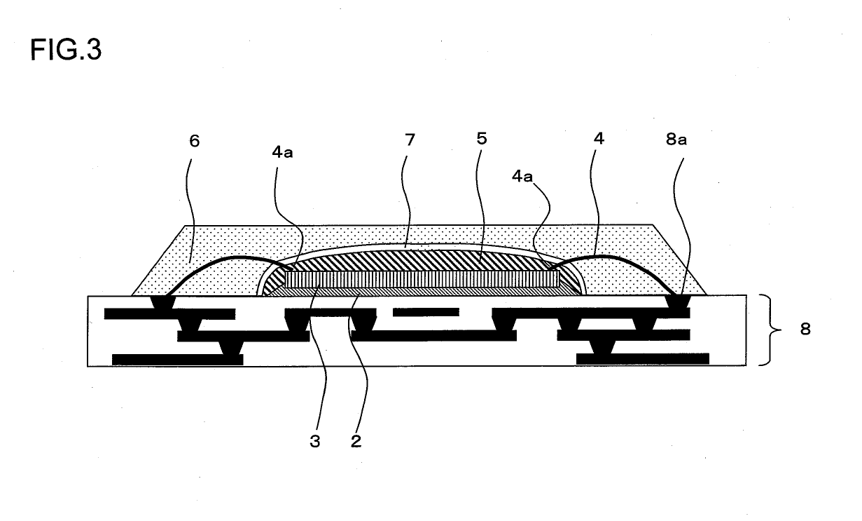

FIG. 3 is a schematic sectional view illustrating the semiconductor device according to Embodiment 2 of the present invention.

The semiconductor device of the present Embodiment 2 comprises a circuit board 8, a semiconductor element 3 mounted on the circuit board 8 via a paste material 2, and bonding metal wires 4 connecting between the semiconductor element 3 and electrode portions 8a disposed on the circuit board 8. Further, in the case of the semiconductor device of the present Embodiment 2, the semiconductor element 3 is covered by a protecting film 5 of water repellent silicone rubber. Connecting portions 4a of the bonding metal wires 4, which have been connected to the semiconductor element 3, are also covered by the protecting film 5 of the water repellent silicone rubber, and sticks to the water repellent silicone rubber. Further more, the whole of the semiconductor element 3, the bonding metal wires 4, and the protecting film 5 of the water repellent silicone rubber are encapsulated with the encapsulation resin 6. By the way, the circuit board 8 of the present Embodiment 2 is one example of a substrate of the present invention. FIG. 3 illustrates that the circuit board 8 is a multilayer circuit board, however, the substrate of the present invention is not limited to this constitution.

In the case of the semiconductor device of the present Embodiment 2, like Embodiment 1, a gap layer 7 is formed between the protecting film 5 and the encapsulation resin 6. Generating of stress caused by heat modification of each member of the semiconductor device can be relieved, because the gap layer 7 is formed like this. Further, since the protecting film 5 of water repellent silicone rubber is used, the fall of reliability resulting from the permeation of the water from the outside can be suppressed. Therefore, long-life of the semiconductor device is realizable.

Next, a method for manufacturing the semiconductor device of Embodiment 2 according to the present invention will be described.

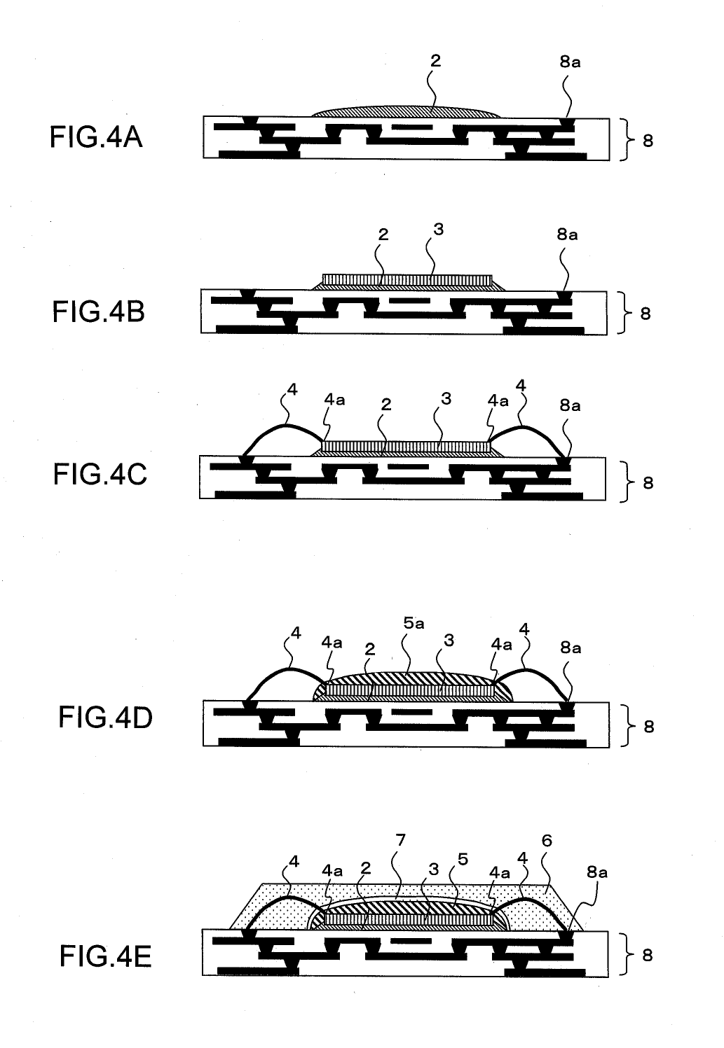

Each of FIGS. 4A to 4E is schematic sectional view illustrating the method for manufacturing the semiconductor device according to Embodiment 2.

As shown in FIG. 4A, an appropriate quantity of a conductive paste material 2 is applied on the circuit board 8. Further, as shown in FIG. 4B, the semiconductor element 3 is mounted on the paste material 2. A known dispenser can be used in case of the application of the paste material 2, and a known die bonder can be used in case of mounting the semiconductor element 3.

Then, as shown in FIG. 4C, the semiconductor element 3 and the electrode portions 8a of the circuit board are joined electrically and mechanically with the bonding metal wires 4. A known wire bonder can be used in case of bonding the bonding metal wires 4.

Then, as shown in FIG. 4D, an appropriate quantity of a silicone rubber monomer 5a that is a precursor of the protecting film 5 is dropped on a portion of the semiconductor element 3, which comes in contact with air, and is dropped on a portion of the paste material 2, which comes in contact with air. In this case, silicone rubber monomer 5a is dropped also on the connecting portions 4a of the bonding metal wires 4, which have been connected to the semiconductor element 3. It is preferable that the quantity of the silicone rubber monomer 5a to be dropped becomes the thickness, which is not less than 10 μm and not more than 2000 μm, of the silicone rubber cured by the method described later. If the thickness of the silicone rubber is less than 10 μm, it is not expectable that thermal stress which is generated at the time of heating in the reflow process and the like is relaxed enough. If the thickness of the silicone rubber is more than 2000 μm, since the thickness of the encapsulation resin 6 becomes thin as described later, the strength of the thin portion of the encapsulation resin 6 becomes weak.

As the silicone rubber monomer 5a, the same mixture as the material described in the method for manufacturing of the semiconductor device of Embodiment 1 can be employed. After the silicone rubber monomer 5a is dropped, the dropped silicone rubber monomer 5a is heated at 150° C. for 4 hours, and as a result, the protecting film 5 is obtained. By the way, the above mentioned process of dropping the silicone rubber monomer 5a corresponds to one example of a process (a putting process) of the present invention, in which a precursor of a protecting film is putted so as to cover at least a part of a semiconductor element mounted on a substrate. The above mentioned process of heating the dropped silicone rubber monomer 5a corresponds to one example of a process (a polymerization process) of the present invention, in which the protecting film is formed due to polymerization of the precursor.

The semiconductor element 3 shown in FIG. 4D, which has been covered with the protecting film 5 but has not yet been encapsulated with the encapsulation resin 6, is placed into a sealing mold heated at suitable temperature. Then, as shown in FIG. 4E, only the surface of the circuit board 8 on which the semiconductor element has been mounted is filled with the encapsulation resin 6 of the epoxy system thermosetting resin under pressure in the sealing mold by using the transfer molding method, so that the epoxy system thermosetting resin is cured. The above mentioned process, in which the epoxy system thermosetting resin is filled into the sealing mold with pressure to be cured, corresponds to one example of a process (an encapsulation process) of the present invention, in which the semiconductor element and the protecting film are encapsulated with an encapsulation resin, and, between the protecting film and the encapsulation resin, at least one gap in which the protecting film does not stick to the encapsulation resin is formed. When the epoxy system thermosetting resin(encapsulation resin 6) is cured, the surface of the epoxy system thermosetting resin does not stick to hardening body of the silicone rubber forming the protecting film 5 completely, because the interfacial tension energy of the epoxy system thermosetting resin is not less than 40 mN/m and not more than 60 mN/m. Since the material which has bad wettability to the encapsulation resin 6 is used like this as the material of the protecting film 5, the encapsulation resin 6 does not stick to the protecting film 5 completely, and then the gap layer 7 is formed, so that the semiconductor device of Embodiment 2 according to the present invention as shown in FIG. 3 is produced.

As described below, in the present Embodiment 2, generating of the inferior goods at the time of reflow process because of permeation of the water from the outside can be reduced, and the relief of the internal stress which is caused by the difference of the linear expansion coefficients between encapsulation resin 6 and the other members constituting the semiconductor device can be very effectively performed, and as a result, the semiconductor device having high reliability can be produced.

That is, the protecting film 5 made from hardening body of the silicone rubber has a water repellency, because interfacial tension energy of the protecting film 5 made from hardening body of the silicone rubber is not less than mN/m and not more than 30 mN/m, and on the contrary, interfacial tension energy of water is about 72 mN/m. Therefore, water does not stay in the gap layer 7 between the encapsulation resin 6 made from the epoxy system thermosetting resin and the protecting film 5 made from hardening body of the silicone rubber. Even if the water stays in the gap layer 7, the water can not permeate the hardening body of the silicone rubber, because the hardening body of the silicone rubber has a lower interfacial tension.

Further, because of the existence of the gap layer 7, the relief of the internal stress which is caused by the difference of the linear expansion coefficients between the members constituting the semiconductor device can be very effectively performed. Therefore, according to the present embodiment, the semiconductor device having a long-life property and a high reliability can be provided.

### Embodiment 3

Next, Embodiment 3 according to the present invention will be described in detail below based on the drawings. In the case of a semiconductor device of the present Embodiment 3, a semiconductor element 3 is connected to a circuit board electrically and mechanically with solder, which is different from Embodiment 2. The same reference numerals as them of Embodiment 2 are given to constitutional parts of Embodiment 3 corresponding to thme of Embodiment 2.

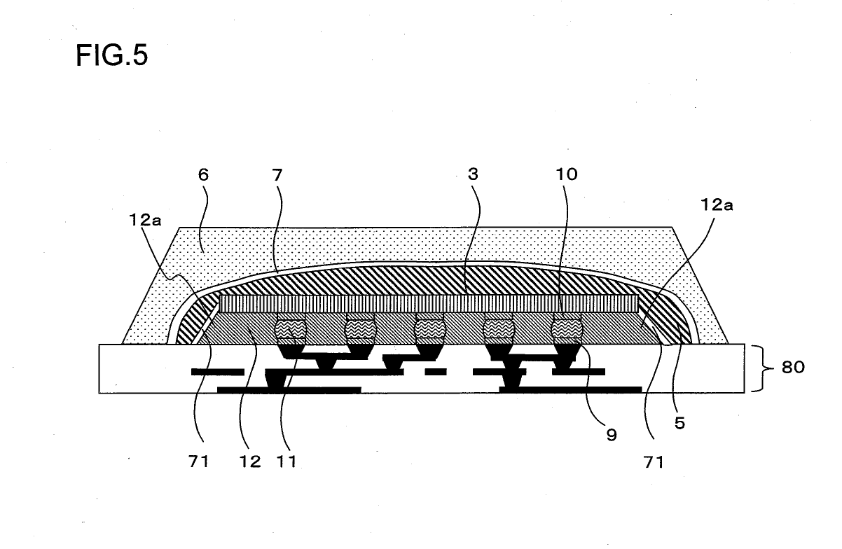

FIG. 5 is a schematic sectional view illustrating a semiconductor device according to Embodiment 3 of the present invention.

The semiconductor device of the present Embodiment 3 comprises a circuit board 80 and a semiconductor element 3. Electrode pads 9 of the circuit board 80 and electrode pads 10 of a semiconductor element 3 are connected electrically and mechanically with soldering portions 11. The region in which the soldering portions 11 are disposed is filled with an underfill resin 12. Further, the semiconductor element 3 and a fillet portion 12a of the underfill resin 12 are covered by the protecting film 5 of the water repellent silicone rubber. Further more, the whole of the semiconductor element 3, the fillet portion 12a of the underfill resin 12, and the protecting film 5 of the water repellent silicone rubber are encapsulated with the encapsulation resin 6. By the way, the circuit board 80 of the present Embodiment 3 is one example of a substrate of the present invention.

Then a gap layer 7 is formed between the protecting film 5 and the encapsulation resin 6, and a second gap layer 71 is formed between the fillet portion 12a of the underfill resin 12 and the protecting film 5.

Generating of stress caused by heat modification of each member of the semiconductor device can be relieved, because the gap layer 7 is formed like this. Further, in the present Embodiment 3, since the second gap layer 71 is also formed, generating of the stress can be more relieved. The fall of reliability resulting from the permeation of the water from the outside can be also suppressed, and the semiconductor device having a long-life can be provided.

Next, a method for manufacturing the semiconductor device of Embodiment 3 according to the present invention will be described.

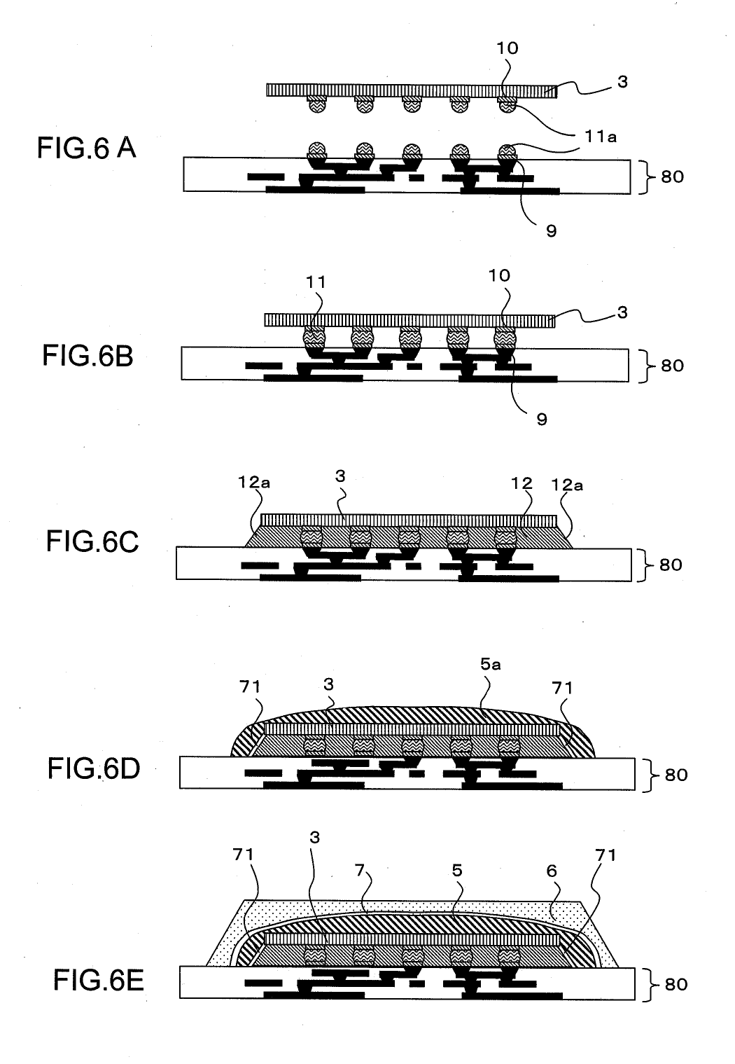

Each of FIGS. 6A to 6E is a schematic sectional view illustrating a method for manufacturing the semiconductor device according to Embodiment 3.

As shown in FIG. 6A, the circuit board 80 is provided with the electrode pads 9 thereon, and the semiconductor element 3 is provided with the electrode pads 10 thereon. Further, solder balls 11a are disposed on the electrode pads 9 and 10 respectively.

Next, as shown in FIG. 6B, the electrode pads 9 and the electrode pads 10 are connected with the solder ball 11a based on a known flip chip bonding method described below. That is, in the flip chip bonding method, the temperature of the circuit board 80 and the semiconductor element 3 is set as 170° C. before connection. Then, the process shifts to alignment by image recognition and the subsequent connection process. In the connection process, the pressure at the time of pressurization is set as 0.1N, and the circuit board 80 and the semiconductor element 3 can be connected by raising the setting temperature of the equipment from 170° C. to 300° C. and heating them in three seconds.

Next, as shown in FIG. 6C, the gap between the circuit board 80 and the semiconductor element 3 which are connected by the flip chip bonding method is filled with an underfill resin 12, and the underfill resin 12 is cured. In the filling process of the underfill resin 12, a known dispenser can be used to fill the underfill resin 12 based on a known method. That is, an appropriate quantity of the underfill resin 12 is dropped on at least one place of end portion of the gap between the circuit board 80 and the semiconductor element 3. Then, the gap among the circuit board 80, the semiconductor element 3 and the soldering portions 11 is appropriately filled with the underfill resin 12 due to capillary action. After the filling the gap, the underfill resin 12 is heated, for example, at 165° C. for 2 hours so that the underfill resin 12 is cured due to the heat, and as a result, the filling process of the underfill resin 12 is completed.

Then, as shown in FIG. 6D, an appropriate quantity of a silicone rubber monomer 5a that is a precursor of the protecting film 5 is dropped so as to cover the semiconductor element 3 and the fillet portion 12a of the underfill resin 12. It is preferable that the quantity of the silicone rubber monomer 5a to be dropped becomes the thickness, which is not less than 10 μm and not more than 2000 μm, of the silicone rubber cured by the method described later. If the thickness of the silicone rubber is less than 10 μm, it is not expectable that thermal stress which is generated at the time of heating in the reflow process and the like is relaxed enough. If the thickness of the silicone rubber is more than 2000 μm, as described later, the thickness of the encapsulation resin 6 becomes thin, and as a result, the strength of the thin portion of the encapsulation resin 6 becomes weak.

As the silicone rubber monomer 5a, the same mixture as the material described in the method for manufacturing of the semiconductor device of Embodiment 1 can be employed. After the silicone rubber monomer 5a is dropped, the dropped silicone rubber monomer 5a is heated at 150° C. for 4 hours, and as a result, the protecting film 5 is obtained.

In this process, the second gap layer 71 is formed between the fillet portion 12a of the underfill resin 12 and the protecting film 5. That is, since the epoxy system thermosetting resin is used as the underfill resin 12, the second gap layer 71 is formed by the difference of each interfacial tension energy when the protecting film 5 made from hardening body of the silicone rubber is formed.

By the way, the above mentioned process of dropping the silicone rubber monomer 5a corresponds to one example of a process (a putting process) of the present invention, in which a precursor of a protecting film is putted so as to cover at least a part of a semiconductor element mounted on a substrate. The above mentioned process of heating the dropped silicone rubber monomer 5a corresponds to one example of a process (a polymerization process) of the present invention, in which the protecting film is formed due to polymerization of the precursor.

The semiconductor element 3 shown in FIG. 6D, which has been covered with the protecting film 5 but has not yet been encapsulated with the encapsulation resin 6, is placed into a sealing mold heated at suitable temperature. Then, as shown in FIG. 6E, only the surface of the circuit board 80 on which the semiconductor element has been mounted is filled with the encapsulation resin 6 of the epoxy system thermosetting resin under pressure in the sealing mold by using the transfer molding method, so that the epoxy system thermosetting resin is cured. The above mentioned process, in which the epoxy system thermosetting resin is filled into the sealing mold with pressure to be cured, corresponds to one example of a process (an encapsulation process) of the present invention, in which the semiconductor element and the protecting film are encapsulated with an encapsulation resin, and, between the protecting film and the encapsulation resin, at least one gap in which the protecting film does not stick to the encapsulation resin is formed. When the epoxy system thermosetting resin(encapsulation resin 6) is cured, the surface of the epoxy system thermosetting resin does not stick to hardening body of the silicone rubber forming the protecting film 5 completely, because the interfacial tension energy of the epoxy system thermosetting resin is not less than 40 mN/m and not more than 60 mN/m. Since the material which has bad wettability to the encapsulation resin 6 is used like this as the material of the protecting film 5, the encapsulation resin 6 does not stick to the protecting film 5 completely, and then the gap layer 7 is formed.

As described above, the semiconductor device of Embodiment 3 shown in FIG. 5 is produced.

As described below, in the present Embodiment 3, generating of the inferior goods at the time of reflow process because of permeation of the water from the outside can be reduced, and the relief of the internal stress which is caused by the difference of the linear expansion coefficients between encapsulation resin 6, underfill resin 12, and the other members constituting the semiconductor device can be very effectively performed, and as a result, the semiconductor device having high reliability can be produced.

That is, the protecting film 5 made from hardening body of the silicone rubber has a water repellency, because interfacial tension energy of the protecting film 5 made from hardening body of the silicone rubber is not less than mN/m and not more than 30 mN/m, and on the contrary, interfacial tension energy of water is about 72 mN/m. Therefore, water does not stay in the gap layer 7 between the encapsulation resin 6 made from the epoxy system thermosetting resin and the protecting film 5 made from hardening body of the silicone rubber. Even if the water stays in the gap layer 7, the water can not permeate the hardening body of the silicone rubber, because the hardening body of the silicone rubber has a lower interfacial tension.

Further, because of the existence of the gap layer 7 and the second gap layer 71, the relief of the internal stress which is caused by the difference of the linear expansion coefficients between the members constituting the semiconductor device can be very effectively performed. Therefore, according to the present embodiment, the semiconductor device having a long-life property and a high reliability can be provided.

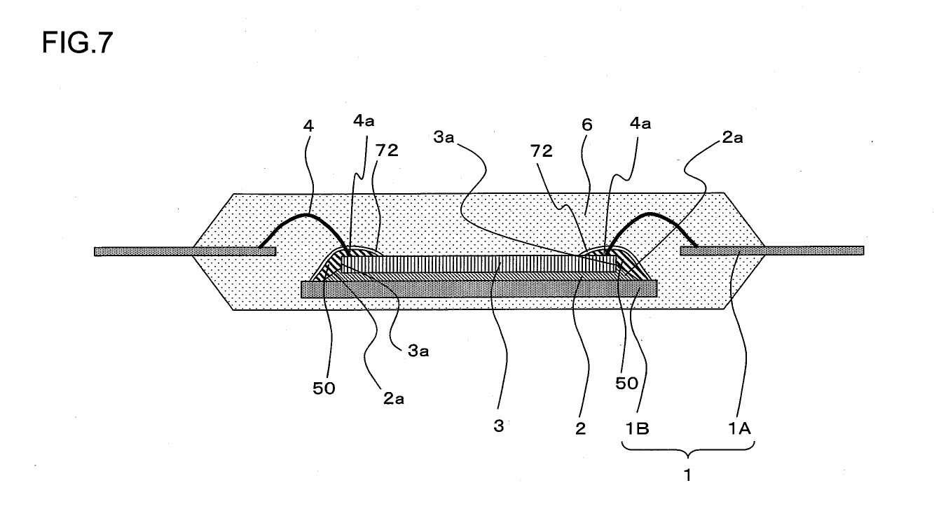

It has been described that the protecting film 5 has been formed so as to cover the whole of the semiconductor element 3 in the above Embodiments 1 to 3. However, the present invention is not limited to this constitution. For instance, a protecting film 50 can be formed so as to cover a part of the semiconductor element 3 as shown in FIG. 7 which is a schematic sectional view illustrating a semiconductor device as a variation of Embodiment 1. In the case of the semiconductor device shown in FIG. 7, the connecting portion 4a of the bonding metal wire 4, which is connected to the semiconductor element 3, end portions (exposed portions) 2a of the paste material 2, and end portions 3a of the semiconductor element 3 are covered by the protecting film 50. The material and the production method of the protecting film 50 are the same as those of the protecting film 5 of Embodiment 1. And a gap layer 72 is formed between the protecting film 50 and the encapsulation resin 6. According to this configuration, the stress applied near the connecting portion 4a can be reduced, and the stay of water can also be prevented.

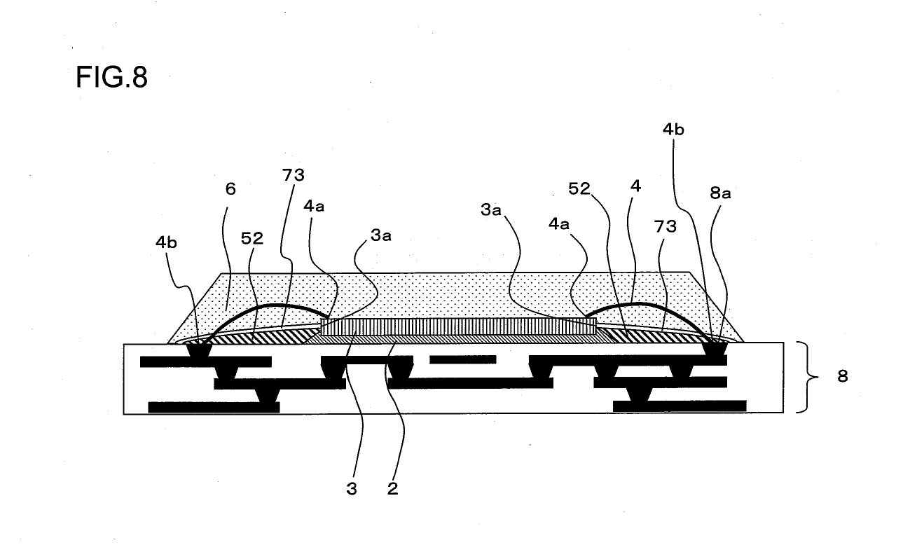

It has been described that the connecting portion 4a of the bonding metal wire 4, which is connected to the semiconductor element 3, is covered by the protecting film 5 in the above Embodiment 2. However, the present invention is not limited to this constitution. For instance, a protecting film 52 can be formed so as to cover a connecting portion 4b of the bonding metal wire 4, which is connected to the electrode portion 8a as shown in FIG. 8 which is a schematic sectional view illustrating a semiconductor device as a variation of Embodiment 2. In the case of the semiconductor device shown in FIG. 8, from the end portion 3a of the semiconductor element 3 to the electrode portion 8a are covered by the protecting film 52. And a gap layer 73 is formed between the protecting film 52 and the encapsulation resin 6. According to this configuration, at least the stress applied to the connecting portion 4b can be reduced, and the stay of water can also be prevented. Further, as shown in FIG. 7, the protecting film can be formed so as to also cover the connecting portion 4a.

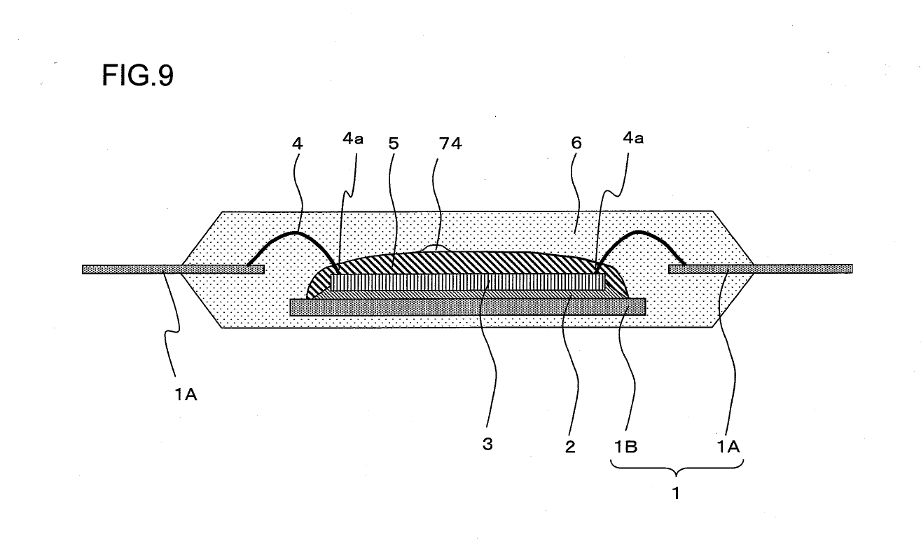

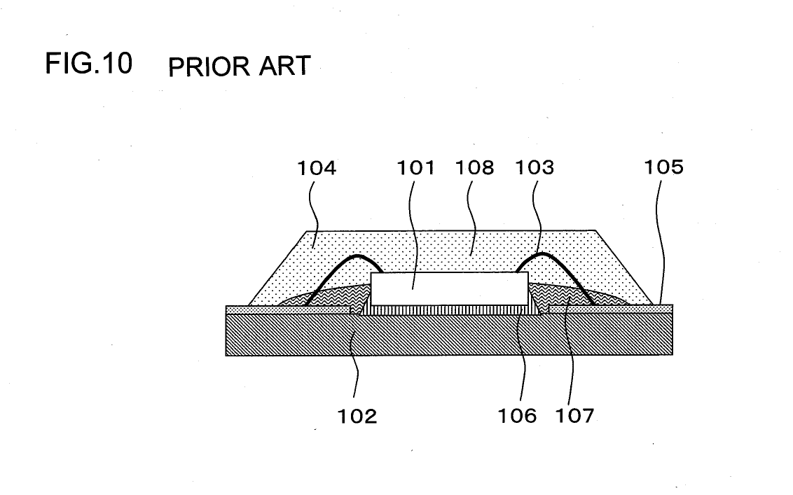

It has been described that the gap layer 7 has been formed throughout the boundary of the protecting film 5 and the encapsulation resin 6 in the above Embodiments 1 to 3. However, the present invention is not limited to this constitution. For instance, the gap layer 7 does not necessarily need to be formed throughout the boundary. Further, it can be allowed that the gap layer 7 is not formed in the shape of a layer. For instance, if only a gap 74 is formed in at least one place of the boundary of the protecting film 5 and the encapsulation resin 6, the stress can be relieved compared with the conventional configuration as shown in FIG. 9 which is a schematic sectional view illustrating a semiconductor device as a variation of Embodiment 1.

The gap of the present invention is formed in size so as to be able to show an effect of the relief of stress, which is issued because the adhesion performance between the encapsulation resin 6 and the protecting film 5 becomes lower by forming the protecting film 5 by using the material having the bad wettability to the encapsulation resin 6.

The gap existing in the interface between the protecting film and the encapsulation resin is especially effective when the semiconductor element is what is called a power device treating large current. The reasons are as follows. Since the element temperature at the time of the drive of the power device rises to 250° C., the stress which is applied to the surrounding encapsulation resin by the thermal expansion of the protecting film can be relieved because of the existing of the gap when the thermal expansion of the protective film which protects the element is occurred.

### INDUSTRIAL APPLICABILITY

According to the present invention, it is possible to provide a semiconductor device having a superior stress-relief performance and a method for manufacturing the same, and is useful as a densification semiconductor package and the like.

### REFERENCE SIGNS LIST

1 Lead frame
1A External terminal
1B Die pad part
2 Paste material
3 Semiconductor element
4 Bonding metal wire
5,50,52 Protecting film
6 Encapsulation resin
7,72,73,74 Gap layer
71 Second gap layer
8 Circuit board
9 Electrode pad
10 Electrode pad
11 Soldering portion
11a Solder ball
12 Underfill resin
12a Fillet portion
101 Semiconductor element
102 Circuit board
103 Bonding metal wire
104 Encapsulation resin layer
105 Circuit board terminal
106 Mounting member
107 Silicone rubber
108 Encapsulation resin

What is claimed is:

1. A semiconductor device comprising:
a substrate;
a semiconductor element which is mounted on the substrate;
a protecting film which covers at least a part of the semiconductor element; and
an encapsulation resin which encapsulates the semiconductor element and the protecting film,
wherein between the protecting film and the encapsulation resin, there is at least one gap in which the protecting film does not stick to the encapsulation resin.

2. The semiconductor device according to claim 1, wherein the protecting film has a water repellency.

3. The semiconductor device according to claim 1, wherein the protecting film is made from a silicone rubber material having interfacial tension energy that is not less than 15 mN/m and not more than 30 mN/m, and
interfacial tension energy of the encapsulation resin is not less than 40 mN/m and not more than 60 mN/m.

4. The semiconductor device according to claim 1, wherein the protecting film has a thickness which is not less than 10 μm and not more than 2000 μm, and
the protecting film has an elastic modulus which is not less than 0.5 MPa and not more than 10 MPa under conditions of 25° C. to 260° C.

5. The semiconductor device according to claim 1, wherein the protecting film is made from a silicone rubber material,
a precursor of the silicone rubber material has an organopolysiloxane framework, and
the precursor is cured in a thermosetting reaction due to a hydrosilylation reaction, so that the precursor becomes silicone rubber having a siloxane framework.

6. The semiconductor device according to claim 1, wherein a thickness of the gap is not less than 0.1 μm and not more than 100 μm.

7. The semiconductor device according to claim 1, wherein the substrate is a lead frame,
the semiconductor element and an external terminal of the lead frame are connected with a bonding metal wire, and
the protecting film covers a connecting portion of the bonding metal wire, at which the bonding metal wire is connected to the semiconductor element.

8. The semiconductor device according to claim 1, wherein the substrate is a circuit board,
the semiconductor element and an electrode portion of the circuit board are connected with a bonding metal wire, and
the protecting film covers a connecting portion of the bonding metal wire, at which the bonding metal wire is connected to the semiconductor element.

9. The semiconductor device according to claim 1, wherein the substrate is a circuit board,
an electrode pad of the semiconductor element and an electrode pad of the circuit board are connected with a soldering portion,
a region in which the soldering portion is disposed is filled with an underfill resin,
the protecting film covers the semiconductor element and a fillet portion of the underfill resin,
the encapsulation resin encapsulates the semiconductor element, the fillet portion of the underfill resin, and the protecting film, and
an another gap is formed between the protecting film and the fillet portion of the underfill resin.

10. The semiconductor device according to claim 1, wherein the encapsulation resin is an epoxy resin,
the protecting film is made from a silicone rubber material,
a precursor of the silicone rubber material has an organopolysiloxane framework, and
the precursor is cured in a thermosetting reaction due to a hydrosilylation reaction, so that the precursor becomes silicone rubber having a siloxane framework.

11. A method for manufacturing a semiconductor device comprising:
putting a precursor of a protecting film so as to cover at least a part of a semiconductor element mounted on a substrate;
forming the protecting film due to polymerization of the precursor; and
encapsulating the semiconductor element and the protecting film with an encapsulation resin, and forming, between the protecting film and the encapsulation resin, at least one gap in which the protecting film does not stick to the encapsulation resin.

12. The method for manufacturing a semiconductor device according to claim 11,
wherein the precursor of the protecting film is a silicone rubber monomer.

13. The method for manufacturing a semiconductor device according to claim 11,
wherein in the case of encapsulating the semiconductor element and the protecting film with the encapsulation resin, the encapsulation resin is made from material which has bad wettability to the protecting film.
